(19) United States
(12) Patent Application Publication
(10) Pub. No.: US 2026/0133223 A1
(43) Pub. Date: May 14, 2026

(54) HIGH-VOLTAGE SURGE TESTING

(71) Applicant: AVO Multi-Amp Corporation d/b/a Megger, Fort Collins, CO (US)

(72) Inventors: Corey FARRELL, Fort Collins, CO (US); Brandon LIND, Eaton, CO (US); Sean HANNI, Fort Collins, CO (US); Gabrielian TAYLOR, Fort Collins, CO (US)

(21) Appl. No.: 18/945,867

(22) Filed: Nov. 13, 2024

(51) Int. Cl. G01R 1/067; G01R 1/073; G01R 27/08

(52) U.S. Cl. CPC G01R 1/06777; G01R 1/06788; G01R 1/07392; G01R 27/08

(57) ABSTRACT

The present disclosure relates to probes and apparatuses for high-voltage surge testing of a device under test. The probes comprises a handle configured to be gripped by an operator to position the probe onto the DUT, an adapter configured to releasably attach a proximal end of a contact electrode to the handle, a current conductor configured to couple the contact electrode to a high-voltage surge generator to deliver a high-voltage surge current to the DUT via a distal end of the contact electrode, and a voltage measurement conductor configured to couple the contact electrode to a voltage measurement circuit. Biasing mechanisms allowing the contact electrode to move into the adapter when the distal end is pressed against the DUT, as well as trigger mechanisms for triggering the delivery of the high-voltage surge current, are also disclosed.

### BACKGROUND

### Technical Field

The present disclosure relates to high-voltage testing of devices under test, such as armatures of electrical machines, and more specifically to probes and apparatuses for such high-voltage surge testing.

### Description of the Related Technology

Electric motors, generators, and other devices with wound components, such as armatures with commutators, may be subjected to surge testing to assess the integrity of their winding insulation. Surge testing may be employed to identify potential weaknesses in insulation, as well as faults between winding turns. These types of faults, if undetected, can lead to short circuits, reduced performance, or premature motor failure. By analyzing impedance characteristics during surge testing, it may be possible to confirm that the motor or component meets quality and reliability standards.

In a typical surge test, a high-voltage pulse is applied to the component to stress its insulation beyond normal operation conditions. To achieve these high-voltages – often reaching up to several kilovolts – it may be necessary to match the impedance between the testing equipment and the device under test. This may be especially necessary for an armature, which typically has a low, primarily inductive impedance due to its windings.

Designing high-voltage test equipment presents challenges, especially in relation to operator safety. High voltages require robust insulation and containment to prevent accidental contact with live parts. Flexibility and versatility are also of interest, enabling the probes to access hard-to-reach test locations without exposing the operator to risk.

### SUMMARY

In some examples, a probe is provided, which may be used for high-voltage surge testing of a device under test, DUT. The probe comprises a handle configured to be gripped by an operator to position the probe onto the DUT, and an adapter configured to releasably attach a proximal end of a contact electrode to the handle. The probe may further comprise a current conductor configured to couple the contact electrode to a high-voltage surge generator to deliver a high-voltage surge current to the DUT via a distal end of the contact electrode, and a voltage measurement conductor configured to couple the contact electrode to a voltage measurement circuit.

In some examples, the adapter may comprise a biasing mechanism configured to allow the contact electrode to move into the adapter when the distal end is pressed against the DUT.

In some examples, the probe may comprise an operator-actuated trigger mechanism configured to assume at least a neutral state, a first actuation state, and a second actuation state. Each of the first and second actuation states may be configured to trigger the delivery of the high-voltage surge current to the DUT.

In some examples, the adapter comprises a sleeve and the biasing mechanism an insert, which may be configured to releasably engage the proximal end of the contact electrode and to move between an extended position and a retracted position within the sleeve.

In some examples, the biasing mechanism comprises a spring configured to push the insert towards the extended position.

In some examples, the insert comprises a rotation stop configured to prevent the insert from rotating within the sleeve.

In some examples, the insert comprises a threading and/or a bayonet coupling configured to releasably engage the proximal end of the contact electrode.

In some examples, the current conductor and the voltage measurement conductor are electrically connected to the sleeve.

In some examples, the handle comprises a finger guard arranged adjacent to the adapter to prevent the operator’s hand from slipping towards the contact electrode.

In some examples, the trigger mechanism comprises a feedback mechanism comprising a first retractable plunger configured to engage with a first mating structure in response to the trigger mechanism assuming the first actuation state, and a second retractable plunger configured to engage with a second mating structure in response to the trigger mechanism assuming the second actuation state.

In some examples, the trigger mechanism comprises an actuator and at least one switch configured to trigger the delivery of the high-voltage surge current. The actuator may be arrangeable in a first position to actuate the at least one switch, and a second position to actuate the at least one switch. In some examples, the trigger mechanism comprises a first switch configured to be actuated by the actuator in the first position and a second switch configured to be actuated by the actuator in the second position.

In some examples, the actuator is configured to pivot around a pivot point to assume the first position and the second position.

In some examples, the trigger mechanism comprises a spring arrangement configured to push the actuator from each of the first and second positions into a neutral position.

In some examples, an apparatus for high-voltage surge testing of a DUT is provided, comprising a first probe and a second probe which may be configured similarly to any of the above-mentioned probes. The first probe may be configured to electrically contact a first test location of the DUT and the second probe to electrically contact a second test location of the DUT. The apparatus may further comprise a high-voltage surge generator coupled to the first and second probes and configured to deliver a high-voltage surge current passing between the first test location and the second test location. Each of the first and second probes may comprise a respective contact electrode for engaging the respective test location, and a respective trigger mechanism configured such that concurrent actuation of both trigger mechanisms triggers the delivery of the high-voltage surge current to the DUT.

In some examples, the first and second trigger mechanisms are configured such that deactivation of at least one of them causes the delivery of the high-voltage surge current to be terminated.

In some examples, the apparatus further comprises processing circuitry configured to determine an electrical impedance of the DUT based at least in part on the high-voltage surge current and the voltage difference.

### BRIEF DESCRIPTION OF THE DRAWINGS

The detailed description is described with reference to the accompanying figures. The use of the same reference numbers in different figures indicates similar or identical components or features.

FIG. 1A schematically illustrates a cross section of a probe comprising a handle, an adapter for releasably attaching a contact electrode to the handle, and a user-actuated trigger mechanism for triggering the delivery of a surge current to the device under test.

FIG. 1B schematically illustrates an adapter comprising a biasing mechanism allowing the contact electrode to move into the adapted when a distal end of the contact electrode is pressed against the device under test.

FIG. 1C is an exploded view of the adapter in FIG. 1B.

FIG. 1D schematically illustrates the trigger mechanism, which is configured to assume at least a neutral state, a first actuation state, and a second actuation state.

FIG. 2 schematically illustrates a first and a second probe for high-voltage surge testing of a device under test.

FIG. 3 schematically illustrates an apparatus comprising a first probe, a second probe, a high-voltage surge current generator, and a voltage measurement circuit.

### DETAILED DESCRIPTION OF CERTAIN INVENTIVE EMBODIMENTS

Embodiments of this application relate to probes and apparatuses for surge testing of a device under test, DUT. The surge test may provide a diagnostic procedure for assessing the insulation integrity and winding condition of electrical equipment, such as electric motors, generators, transformers, and other devices with wound components, such as armatures with commutators. The test may be performed by applying a high-voltage surge, or pulse, to the windings, using a surge tester that generates short, high-energy bursts. The test voltage may be applied to the winding in pulses, and the resulting electrical response may be monitored and recorded, often as a waveform on an oscilloscope or specialized equipment.

During a surge test, the pulse may create a high-voltage stress across the insulation within the windings. By examining the resulting waveforms, technicians can identify discrepancies in the equipment’s internal structure. Specifically, the test can detect insulation weaknesses, partial discharge, or faults between turns, coils, or phases within the windings. For example, a well-functioning winding typically produces a predicable waveform with a consistent response. Any deviation from this expected waveform – such as irregular peaks or shifts – may indicate a potential fault, short, or degradation of the insulation.

The surge test may begin by charging a capacitor to a high voltage, typically in the range of 500V to several kilovolts, depending on the component specifications and testing requirements. This high-voltage pulse is then rapidly discharged through the DUT via a pair of probes, applying a sudden surge current between the test locations on the DUT. The DUT’s impedance may shape the current waveform, producing a characteristic oscillation pattern. One metric derived from the surge test may be the Error Area Ratio (EAR), which quantifies the difference between the test waveform and a reference waveform. A high EAR may indicate significant deviation, suggesting potential insulation weaknesses or manufacturing defects. By comparing waveforms at different test voltages or over repeated surges, engineers can identify latent faults that may not appear at lower voltages.

In an example, a probe for surge testing of a DUT is provided. The probe comprises a handle configured to be gripped by an operator to position the probe onto the DUT, and an adapter configured to releasably attach a proximal end of a contact electrode to the handle. The probe may further comprise a current conductor configured to couple the contact electrode to a surge generator to deliver a surge current to the DUT via a distal end of the contact electrode, and a voltage measurement conductor configured to couple the contact electrode to a voltage measurement circuit.

In an example, the adapter comprises a biasing mechanism configured to allow the contact electrode to move into the adapter when the distal end is pressed against the DUT.

The contact electrode may form a conductive element designed to establish an electrical connection with a DUT during surge testing. Structurally, it typically comprises a distal end that makes physical contact with the DUT and a proximal end that connects to the probe and the surge generator. The contact electrode may also be referred to as a probe tip, tip, or conductive probe element.

The contact electrode may be spring-biased to maintain consistent pressure against the DUT. This consistency may improve the reliability of the test by reducing variations caused by differing operator pressures, relative movement between the probe and the DUT, or irregular surface contours of the DUT. Further, the biasing mechanism may help absorbing mechanical shocks during handling or testing, reducing the likelihood of bending or breaking the contact electrode and damaging the surface of the DUT.

The releasable attachment of the contact electrode allows for easy replacement of worn or damaged contact electrodes. Further, releasable contact electrodes allow for the probe to be adapted to various testing scenarios and facilitate access to hard-to-reach test locations.

In some examples, the contact electrode, or at least its distal tip, may be formed of a material that is relatively soft so as to reduce the risk of damaging the surface of the DUT. The material may even be softer than the material of the DUT. This may be particularly advantageous when testing components such as commutators, which are often formed of relatively soft copper. Harder contact electrodes, such as those made of steel, could easily damage the surface of the DUT if excessive pressure is applied.

In an example, a probe for surge testing of a DUT is provided, which comprises a handle configured to be gripped by an operator to position the probe onto the DUT, and an adapter configured to releasably attach a proximal end of a contact electrode to the handle. The probe further comprises a current conductor configured to couple the contact electrode to a surge generator to deliver a surge current to the DUT via a distal end of the contact electrode, and a voltage measurement conductor configured to couple the contact electrode to a voltage measurement circuit. An operator-actuated trigger mechanism may also be provided, configured to assume at least a neutral state, a first actuation state, and a second actuation state. Each of the first and second actuation states may be configured to trigger the delivery of the surge current to the DUT.

The ability to actuate the trigger mechanism in two different directions may provide greater ergonomic flexibility for the operator. This may be especially beneficial when testing in confined spaces or at awkward angles, as the operator can choose the most comfortable or accessible direction to initiate the surge. Further, by allowing the surge to be triggered through distinct actuation states, a level of redundancy may be provided. This may ensure that even if one actuation direction becomes difficult or fails, the operator can still perform the test using the alternative direction.

In some examples, the handle is configured to allow the operator to grip the probe in different orientations. This may be achieved, for example, by an L-shaped or pistol-like handle which can be gripped at either “leg” to provide better maneuverability when accessing tight or awkward test locations. The operator can select the most suitable grip for reaching different angles. When combined with the above-mentioned trigger mechanism, which can be actuated in either direction, this design may minimize hand fatigue and make the probe more adaptable to various hand positions and testing angles. The operator may shift between grip positions while maintaining the ability to trigger the surge from either direction.

In some examples, the probe comprises a feedback mechanism configured to generate feedback as the trigger mechanism assumes the first and/or second actuation states. The feedback may be tactile, providing a physical sensation such as a click or resistance when the trigger is actuated. This may ensure that the operator is aware that the trigger has been successfully engaged. Alternatively, or additionally, the feedback may be audible. Further, the feedback may provide a distinct point at which the surge is initiated, reducing the likelihood of accidental or premature activation. Operator may feel the exact moment of engagement, allowing for more deliberate and controlled operation. The feedback may also reduce the risk of unintentional contact with live parts, such as the contact electrode.

In an example, an apparatus for surge testing of a DUT is provided. The apparatus comprises a first probe configured to electrically contact a first test location on the DUT and a second probe configured to electrically contact a second test location of the DUT. The apparatus further comprises a surge generator, such as a high-voltage surge generator, coupled to the first and second probes and configured to deliver a surge current passing between the first test location and the second test location, and a voltage measurement circuit coupled to the first and second probes and configured to determine a voltage difference between the first test location and the second test location. The first probe comprises a first contact electrode, configured to engage the first test location, and a first trigger mechanism. The second probe comprises a second contact electrode, configured to engage the second test location, and a second trigger mechanism. The first and second trigger mechanisms are configured such that concurrent actuation of the first trigger mechanism and the second trigger mechanism triggers the delivery of the surge current to the DUT. The first and second trigger mechanisms may be configured such that concurrent actuation is required to deliver the surge, and such that deactivation of at least one of them causes the delivery of the surge to be terminated.

Requiring both hands to engage the triggers helps ensuring that the surge cannot be triggered accidentally by a single hand or unintended contact. This reduces the risk of accidental high-voltage surges, protecting both the operator and the equipment. Further, by necessitating the use of both hands on the probes, the operator’s hands are kept away from the high-voltage areas of the DUT, reducing the risk of electric shock or injury.

The surge testing according to the present disclosure may involve a so-called pseudo-Kelvin resistance measurement, utilizing two contact electrodes instead of the traditional four used in standard Kelvin measurement. In four-wire Kelvin measurements, separate probe tips are used for delivering the surge current and for measuring the voltage drop. Separating the current and voltage paths may reduce the risk that the measured voltage drop is influenced by the resistance of the current path. This may however come at the cost of increased complexity, as the testing requires four contact points on the DUT and separate current and voltage paths to the handled.

In the pseudo-Kelvin configuration according to the present disclosure, the contact electrodes serve a dual purpose. They may not only deliver the surge current but also act as points for voltage measurement. The voltage measurement conductors may be attached directly to these contact electrodes, reducing the distance between the test location on the DUT and the voltage measurement conductor. As the surge current is applied through the contact electrodes, the voltage drop across the DUT may be measured simultaneously. This approach may effectively eliminate the influence of lead resistance, as in a traditional four-wire Kelin setup, with only a minimal resistance contribution from the contact electrodes themselves. Given that the load under test is primarily inductive and represents a significantly higher impedance than the relatively short, negligible-inductance contact electrodes, this configuration may provide accurate measurements without substantial impedance distortions.

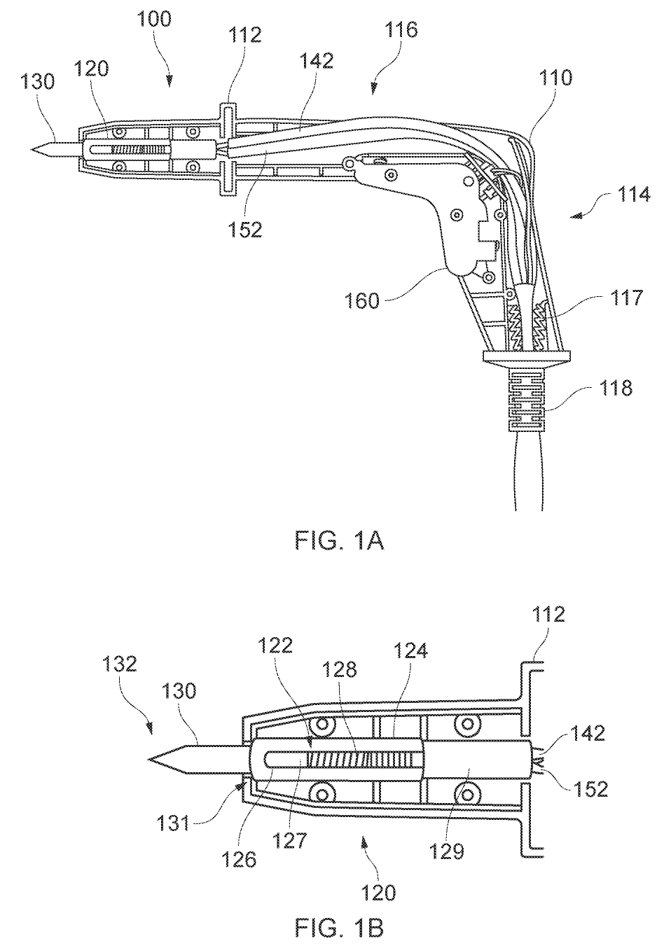

FIG. 1A is a schematic cross section of a probe 100 according to an example, which can be used for surge testing as outlined above. The probe 100 comprises a handle 110, which may be formed as a pistol-like, L-shaped structure comprising a first and a second distinct grip sections, one forming the first leg 114 and the other forming the second leg 116 of the L-shape. Each grip section 114, 116 may be contoured and textured to provide a secure hold, allowing the operator to choose between two different orientations depending on the testing scenario. The handle 110 may be formed from a durable, non-conductive material, such as plastic, to ensure safety during high-voltage operation. The handle 110 may, for example, be injected molded or 3D printed.

The handle 110 may further comprise a finger guard 112 positioned at the front of the handle 110, near the contact electrode 130. This guard 112 may be designed to prevent the operator’s fingers from accidentally slipping forward and coming into contact with live parts of the probe, such as the electrically conducting tip 130.

The probe 100 further comprises an adapter 120, which is configured to releasably attach the contact electrode 130 to the handle 110. In the depicted example, the adapter 120 is arranged at least partly within the body of the handle 110 and configured to attach the contact electrode 130 such that at least a portion of the contact electrode 130 protrudes from the handle 110 and can be placed onto the DUT.

The adapter 120 may be electrically contacted by electric leads, or conductors, for connecting the contact electrode 130 to a high-voltage surge generator and a voltage measurement circuit (not shown). In the present example, a current conductor 142 and a voltage measurement conductor 152 are attached to the adapter 120 and extend backwards through the handle 110, away from the adapter, through the second and first grip sections 114, 116 to a rear part of the handle 110. The rear part of the handle may comprise a tooth-gripping mechanism 117 to immobilize the conductors 142, 152. In some examples, a clamp 118 may be provided to provide strain relief and secure the conductors 142, 152 to the handle 110.

In some examples, the probe 100 comprises a trigger mechanism 160, by means of which the operator can trigger the delivery of the high-voltage surge current to the DUT. The trigger mechanism 160 may hence be referred to as an operator-actuated trigger mechanism 160. The trigger mechanism 160 may be actuated when the handle 110 is held in either of the orientations described above, i.e., when the operator grips the first grip section 114 or the second grip section 116. This allows for the operator to trigger the delivery of the surge from different orientations, depending on the testing scenario. The trigger mechanism 160 will be described in further detail in connection with FIG. 1D.

The adapter 120 may comprise a biasing mechanism allowing the contact electrode 130 to move into the adapter 120 when the contact electrode 130 is pressed against the DUT. An example of such a configuration will now be discussed with reference to FIGS. 1B and C.

FIG. 1B shows a detail of the front portion of the probe 100 in FIG. 1A, including an example configuration of the adapter 120 and the contact electrode 130. In this particular example, the adapter 120 comprises a sleeve 124 and an insert 126 for releasably engaging a proximal end 131 of the contact electrode 130. The insert 126 is arranged to slide back and forth within the sleeve 124 to allow the contact electrode 130 to move into the adapter 120 when pressed against the DUT. This allows the contact electrode 130 to move between an extended position, in which the distal end 132 has been moved away from the adapter 120, and a retracted position in which the distal end 132 has been moved towards (or even into) the adapter 120. Further, a spring 128 may be provided to compress and retract as the insert 126 reciprocates within the sleeve 124. The spring 128 may be configured to push the contact electrode 130 towards the extended position, and to counteract its retraction into the adapter 120. As a result, the contact electrode 130 may assume the extended position when in a normal, resting state, and pushed towards the retracted position when engaging the DUT, maintaining a certain contact pressure.

The adapter may further comprise a contact structure for the current conductor 142 and the voltage measurement conductor 152. The contact structure may comprise a crimped connection, or crimp 129, which may be arranged opposite to the contact electrode 130. The electric path may pass from the crimp 129 through the sleeve 124, the insert 126, and the spring 128 to the contact electrode 130. Alternative contact structures are also possible, such as soldered connections for the conductors 142, 152 to the adapter 120.

As previously mentioned, the contact electrode 130, or at least a portion of the electrode, such as the distal end 132, may comprise a material that is relatively soft compared to the surface of the DUT 10, as this may help to reduce the risk of damaging the surface of the DUT 10. Various metals and alloys may be considered. An example of such a material is brass C360, which is known for its relatively high conductivity (26% IACS; the International Annealed Copper Standard) and a balanced hardness that may help prevent damage to both the DUT 10 and the contact electrode 130. With a Brinell hardness rating of 100-160 BHN, brass C360 is softer than steel, which reduces the risk of scratching or damaging, e.g., the commutator surface. Yet, it is still stronger than copper, which helps protecting the contact electrode from excessive wear.

Brass C314 is another example, which may offer even better conductivity at 33% IACS. This alloy is softer than brass C360 due to its lower zinc content, giving it a Brinell hardness rating of 65-120 BHN. This softness may further reduce the risk of damaging sensitive surfaces such as that of a commutator.

For applications requiring even softer materials to further reduce the potential impact on the DUT 10, carbon/graphite may be an option. This material typically offers a relatively high conductivity and a Brinell hardness of just 5 BHN. In further examples the contact electrode 130 may comprise silver or gold-plated brass, which may combine the strength of brass with the high conductivity of precious metals.

The releasable attachment of the contact electrode 130 allows for the contact electrode 130 to be replaced based on the sensitivity of the DUT 10.

FIG. 1C shows an exploded view of the adapter 120 and the electrode 130 in FIGS. 1A and B. The contact electrode 130, or probe tip 130, may be attached to the insert 126 by means of a threading 133 at the proximal end 131 of the contact electrode 130. Other attachments are however possible, such as bayonet couplings, or friction couplings. The insert 126 may comprise a rotation stop 127, which in the current example is formed by a lateral protrusion engaging a groove or slit extending along the length of the sleeve 124. The rotation stop 127 may restrict relative movement between the insert 126 and the sleeve 124 to predominantly linear movement along the length of the sleeve 124, thereby allowing the contact electrode 130 to be attached and removed from the adapter 120 by means of the threading 133.

The electrical connection between the contact electrode 130 and the surge generator and the voltage measurement circuit may be provided by conductors 142, 152 attached to the sleeve 124 by means of the crimp 129. The crimp 129 may be attached to the sleeve 124 by means of a threading.

The insert 126 may be pushed towards the extended position by means of the spring 128, which may be arranged to abut the crimp 129 to provide the necessary counterforce as well as electrical connection to the conductors 142, 152.

It should be noted that the biasing mechanism shown in FIGS. 1A-C are merely an example illustrating one possible implementation of the inventive concept. Other realizations of the biasing mechanism are also possible, including bayonet couplings, telescoping mechanisms, and spring-loaded guide rails.

As mentioned above, the probe 100 may comprise a trigger mechanism for triggering the delivery of the surge current to the DUT. An example of such a mechanism 160 is shown in FIG. 1D, which is configured to assume at least two different states: a first actuation state, and a second actuation state. Each of these states may trigger the delivery of the surge current. The trigger mechanism 160 may also be configured to assume a neutral state, in which no surge current is delivered. The trigger mechanism 160 may be configured to actuate a high-voltage switch, such as a triggered spark gap or semiconductor switch, that releases the stored energy from the high-voltage surge generator.

Various configurations are possible. In the depicted example, the trigger mechanism 160 comprises an actuator 161 which is arranged to pivot around a pivot point 163 to trigger the delivery of the surge current. The trigger mechanism 160 can be actuated by either pushing the actuator 161 towards the first grip section 114 (counterclockwise in FIG. 1D) or by pushing the actuator 161 towards the second grip section 116 (clockwise in FIG. 1D). The actuator 161 may be arranged to interact with a switch arrangement, comprising one or more switches 165, 167. In FIG. 1D, the switch arrangement is provided on a printed circuit board arranged close to the pivot point 163. When the operator pushes the actuator 161 towards the first grip section 114, the actuator 161 may cause the first switch 165 to be actuated. When the operation pushed the actuator 161 towards the second grip section 116, the actuator 161 may actuate the second switch 167. Other configurations are however possible, with one or more switches arranged closer to the distal portions of the actuator 161 or comprising other types of switch arrangements.

The trigger mechanism 160 may further comprise a spring arrangement configured to push the actuator 161 from each of the first and second positions into a neutral position. In an example, a first spring 168 may be arranged to push the actuator 161 away from the first grip section 114 and a second spring 169 arranged to push the actuator 161 away from the second grip section 116. In different words, the spring arrangement 168, 169 may be provided to return the actuator mechanism 160 into a neutral state after the delivery of the surge current.

In some examples, the trigger mechanism 160 may comprise a feedback mechanism configured to generate feedback, such as tactile and/or audible feedback, as the trigger mechanism 160 is actuated, i.e., assumes the first and/or second actuation states. The feedback mechanism may, for example, comprise a retractable plunger, or spring-loaded plunger, engaging with a mating structure, such as an intent or protrusion, as the trigger mechanism moves between different actuation states. FIG. 1D shows an example of such feedback mechanism, comprising a first retractable plunger in form of a ball-spring plunger 162, configured to engage with a first mating structure in response to the trigger mechanism assuming the first actuation state. The trigger mechanism 160 may further comprise a retractable plunger in form of a second ball-spring plunger 164 configured to engage with a second mating structure in response to the trigger mechanism assuming the second actuation state. The first and second ball-spring plungers 162, 164 may be attached to the actuator 161, such as at a respective distal portion of the actuator 161 and configured to engage a mating structure attached to a body of the handle 110. A reversed configuration may also be possible, with the ball-spring plungers 162, 164 attached to the body of the handle 110 and the mating structures arranged on the moving actuator 161 instead. In some examples, the mating structures are formed of ball-spring plungers similar to the first and second ball-spring plungers 162, 164.

During operation, pushing the actuator 161 into the first actuation state may cause the first ball-spring plunger 162 to engage the first mating structure, resulting in a distinct, mechanical sensation felt by the operator when the plunger 162 moves past the first mating structure. Similarly, pushing the actuator 161 into the second actuation state may cause the second ball-spring plunger 164 to engage the second mating structure, resulting in a similar mechanical sensation.

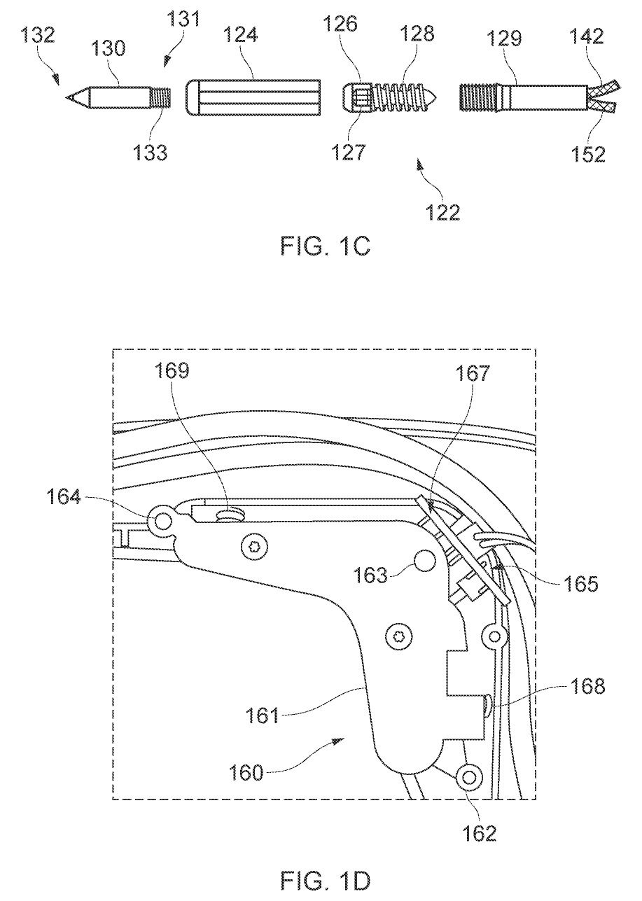

FIG. 2 shows a pair of probes 100, 200 according to an example of the present disclosure. The pair of probes may be configured similarly to the probes discussed above in connection with FIGS. 1A-D. Hence, each of the probes 100, 200 may comprise a handle 110 allowing an operator to grip the probe 100, 200 in at least two different orientations, a trigger mechanism 160, 260 that can be actuated in at least two different directions, and a releasable contact electrode 130, 230 for delivering a surge current to the DUT as well as measuring the resulting voltage drop. The probes 100, 200 may be electrically coupled to a high-voltage surge generator and a voltage measurement circuit (not shown) through conductors 142, 152, 242, 252.

The trigger mechanism 160 of the first probe 100 and the trigger mechanism 260 of the second probe 200 may be configured such that concurrent actuation is required in order to deliver the high-voltage surge current to the test locations. In different words, the operator may have to actuate both trigger mechanisms 160, 260 to perform the testing of the DUT. Deactivating one of the trigger mechanisms 160, 260 may thus lead to the delivery of the high-voltage surge current to be terminated.

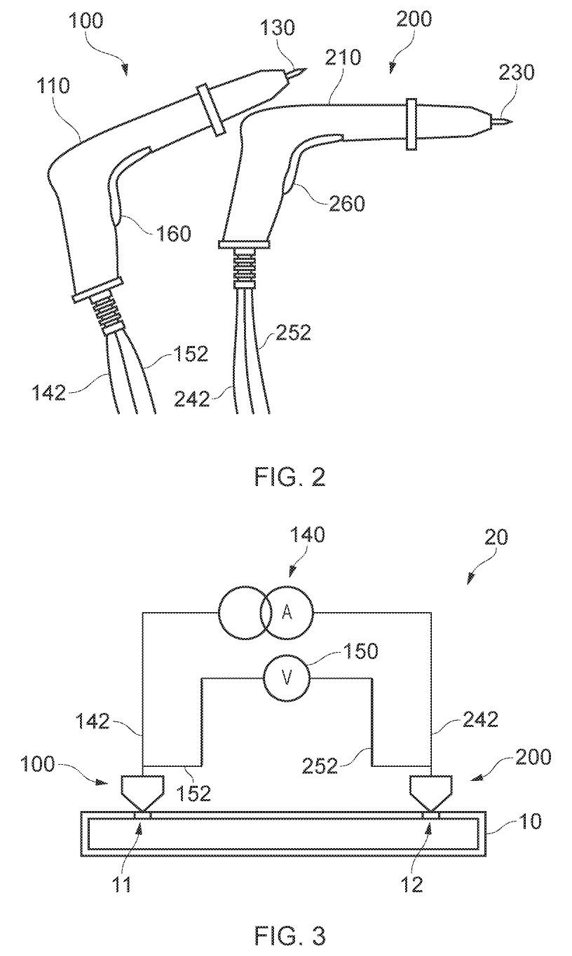

The first and second probes 100, 200 may form part of, or be used in combination with, a surge testing apparatus 20 such as the one schematically illustrated in FIG. 3. The example apparatus 20 comprises a surge generator 140, also referred to as a high-voltage surge current generator. The surge generator 140 is configured to produce controlled, high-voltage pulses or surges for testing DUTs 10, such as motors, generators, transformers, and armatures. The surge generator 140 may comprise a power supply capable of charging a surge capacitor to the desired high-voltage level, typically ranging from 500V up to several kilovolts, depending on the test requirements. The surge capacitor may store energy to be released as a surge pulse, or a high-voltage surge current, to the probes 100, 200 via current conductors 142, 242. The release of the surge pulse may be triggered by a switching mechanism, or HV switch, which may be activated by the operator actuating a trigger mechanism 160, 260 as outlined above. For DUTs 10 with low impedance, such as armatures, the surge generator 140 may include an impedance matching transformer. This transformer may step down the voltage and adjust the impedance to ensure maximum power transfer and effective current flow between the test locations 11, 12 on the DUT 10.

The apparatus 20 may be configured to measure the impedance by means of a voltage measurement circuit 150 connected to separate voltage measurement conductors attached to the contact electrodes 130, 230 of the respective probes 100, 200. Isolating the voltage measurement path from the current path may reduce the influence of lead and contact resistance.

The voltage measurement circuit 150 may be designed to measure the voltage drop across the DUT while the high-voltage surge current, provided by the surge generator 140, flow between the test locations 11, 12 of the DUT 10. The voltage measurement circuit 150 may comprise a high-impedance voltmeter or an oscilloscope configured to detect voltage signals with relatively low current draw, ensuring that the voltage measurements reflect the DUT’s 10 response rather than the resistance of the current-carrying conductors 142, 242.

The voltage measurement circuit 150 may include a high-impedance input, such as a differential amplifier, allowing it to sense the voltage across the DUT 10 without drawing significant current. The circuit 150 may further comprise filtering elements (e.g., capacitors or low-pass filters) to stabilize the measured signal by filtering out noise and oscillations, which may be especially beneficial in high-voltage surge testing where transient noise may be common.

An analog-to-digital converter, ADC, may be used to convert the sensed voltage into a digital signal, which may be processed by a microcontroller or processing unit to calculate the impedance. The impedance may be calculated by dividing the measured voltage drop by the surge current, using Ohm’s law. The impedance may include both the resistive and reactive (inductive or capacitive) components of the DUT 10, offering a comprehensive characteristic of the electrical response to the applied surge.

As indicated in the present figure, the voltage measurement circuit may be connected to separate voltage measurement conductors 152, 252 attached directly to the respective probe 100, 200, preferably as close to the DUT 10 as possible. The voltage measurement conductors 152, 252 may, for example, be attached to a rear portion of the adapter 120 as shown in FIGS. 1A-C.

In the description of examples, reference is made to the accompanying drawings that form a part hereof, which show by way of illustration specific examples of the claimed subject matter. It is to be understood that other examples may be used and that changes or alteration, such as structural changes, may be made. Such examples, changes or alteration are not necessarily departures from the scope with respect to the intended claimed subject matter. While the steps herein may be presented in a certain order, in some cases the ordering may be changed so that certain inputs are provided at different times or in a different order without changing the function of the apparatuses and method described.

Although the subject matter has been described in a language specific to structural features and/or methodological acts, it is to be understood that the subject matter defined in the appended claims is not necessarily limited to the specific features or acts described. Rather, the specific features and acts are disclosed as example forms of implementing the claims.

Conditional language such as, among others, “may,” “could,” “may” or “might,” unless specifically stated otherwise, are understood within the context to present that certain examples include, while other examples do not include, certain features, elements and/or steps. Thus, such conditional language is not generally intended to imply that certain features, elements and/or steps are in any way required for one or more examples or that one or more examples necessarily include logic for deciding, with or without user input or prompting, whether certain features, elements and/or steps are included or are to be performed in any particular example.

Conjunctive language such as the phrase “at least one of X, Y or Z,” unless specifically stated otherwise, is to be understood to present that an item, term, etc. may be either X, Y, or Z, or any combination thereof, including multiples of each element. Unless explicitly described as singular, “a” means singular and plural.

Any routine descriptions, elements or blocks in the flow diagrams described herein and/or depicted in the attached figures should be understood as potentially representing modules, segments, or portions of code that include one or more computer-executable instructions for implementing specific logical functions or elements in the routine. Alternate implementations are included within the scope of the examples described herein in which elements or functions may be deleted or executed out of order from that shown or discussed, including substantially synchronously, in reverse order, with additional operations, or omitting operations, depending on the functionality involved as would be understood by those skilled in the art. Note that the term substantially may indicate a range. For example, substantially simultaneously may indicate that two activities occur within a time range of each other, substantially same dimension may indicate that two elements have dimensions within a range of each other, and/or the like.

Many variations and modifications may be made to the above-described examples, the elements of which are to be understood as being among other acceptable examples. All such modifications and variations are intended to be included herein within the scope of this disclosure and protected by the following claims.

What is claimed is:

1. A probe for high-voltage surge testing of a device under test, DUT, comprising:
a handle configured to be gripped by an operator to position the probe onto the DUT;
an adapter configured to releasably attach a proximal end of a contact electrode to the handle;
a current conductor configured to couple the contact electrode to a high-voltage surge generator to deliver a high-voltage surge current to the DUT via a distal end of the contact electrode; and
a voltage measurement conductor configured to couple the contact electrode to a voltage measurement circuit;
wherein the adapter comprises a biasing mechanism configured to allow the contact electrode to move into the adapter when the distal end is pressed against the DUT.

2. The probe of claim 1, wherein the adapter comprises a sleeve, and wherein the biasing mechanism comprises an insert configured to releasably engage the proximal end of the contact electrode and to move between an extended position and a retracted position within the sleeve.

3. The probe of claim 2, wherein the biasing mechanism comprises a spring configured to push the insert towards the extended position.

4. The probe of claim 2, wherein the insert comprises a rotation stop configured to prevent the insert from rotating within the sleeve.

5. The probe of claim 2, wherein the insert comprises at least one of a threading and a bayonet coupling configured to releasably engage the proximal end of the contact electrode.

6. The probe of claim 2, wherein the current conductor and the voltage measurement conductor are electrically connected to the sleeve.

7. The probe of claim 1, wherein the handle comprises a finger guard arranged adjacent to the adapter to prevent the operator’s hand from slipping towards the contact electrode.

8. The probe of claim 1, further comprising an operator-actuated trigger mechanism configured to assume at least a neutral state, a first actuation state, and a second actuation state, each of the first and second actuation states configured to trigger the delivery of the high-voltage surge current to the device under test.

9. The probe of claim 8, wherein the trigger mechanism further comprises a feedback mechanism comprising a first retractable plunger configured to engage with a first mating structure in response to the trigger mechanism assuming the first actuation state, and a second retractable plunger configured to engage with a second mating structure in response to the trigger mechanism assuming the second actuation state.

10. A probe for high-voltage surge testing of a device under test, DUT, comprising:
a handle configured to be gripped by an operator to position the probe onto the DUT;
an adapter configured to releasably attach a proximal end of a contact electrode to the handle;
a current conductor configured to couple the contact electrode to a high-voltage surge generator to deliver a high-voltage surge current to the DUT via a distal end of the contact electrode;
a voltage measurement conductor configured to couple the contact electrode to a voltage measurement circuit; and
an operator-actuated trigger mechanism configured to assume at least a neutral state, a first actuation state, and a second actuation state, each of the first and second actuation states configured to trigger the delivery of the high-voltage surge current to the device under test.

11. The probe of claim 10, wherein:
the trigger mechanism comprises an actuator and at least one switch configured to trigger the delivery of the high-voltage surge current; and
the actuator is arrangeable in a first position and a second position, each of which configured to actuate the at least one switch.

12. The probe of claim 11, wherein the actuator is configured to pivot around a pivot point to assume the first position and the second position.

13. The probe of claim 11, wherein the trigger mechanism further comprises a spring arrangement configured to push the actuator from each of the first and second positions into a neutral position.

14. The probe of claim 10, further comprising a feedback mechanism configured to generate tactile feedback as the trigger mechanism assumes the first and/or second actuation states.

15. The probe of claim 14, wherein the tactile feedback mechanism comprises a first retractable plunger configured to engage with a first mating structure in response to the trigger mechanism assuming the first actuation state, and a second retractable plunger configured to engage with a second mating structure in response to the trigger mechanism assuming the second actuation state.

16. The probe of claim 10, wherein the adapter comprises a biasing mechanism configured to allow the contact electrode to move into the adapter when the distal end of the contact electrode is pressed against the device under test.

17. The probe of claim 10, wherein the adapter comprises a sleeve, and wherein the biasing mechanism comprises an insert configured to releasably engage the proximal end of the contact electrode and to move between an extended position and a retracted position within the sleeve.

18. An apparatus for high-voltage surge testing of a device under test, DUT, comprising:
a first probe configured to electrically contact a first test location of the DUT;
a second probe configured to electrically contact a second test location of the DUT;
a high-voltage surge generator coupled to the first and second probes and configured to deliver a high-voltage surge current passing between the first test location and the second test location;
a voltage measurement circuit coupled to the first and second probes and configured to determine a voltage difference between the first test location and the second test location;
wherein the first probe comprises:
a first contact electrode configured to engage the first test location, and
a first trigger mechanism;
wherein the second probe comprises:
a second contact electrode configured to engage the second test location, and
a second trigger mechanism; and
wherein the first and second trigger mechanisms are configured such that concurrent actuation of the first trigger mechanism and the second trigger mechanism triggers the delivery of the high-voltage surge current to the DUT.

19. The apparatus of claim 18, wherein the first and second trigger mechanisms are configured such that deactivation of at least one of the first and second trigger mechanisms causes the delivery of the high-voltage surge current to be terminated.

20. The apparatus of claim 18, further comprising processing circuitry configured to determine an electrical impedance of the DUT based at least in part on the high-voltage surge current and the voltage difference.
